(19) United States
(12) Patent Application Publication
(10) Pub. No.: US 2024/0237423 A1
(43) Pub. Date: Jul. 11, 2024

(54) DISPLAY DEVICE

(71) Applicant: Samsung Display Co., LTD., Yongin-si (KR)

(72) Inventors: JUNGI KIM, Yongin-si (KR); HYE SUN KIM, Yongin-si (KR); SANGHYUN YUN, Yongin-si (KR); GWANGMIN CHA, Yongin-si (KR)

(73) Assignee: Samsung Display Co., LTD., Yongin-si (KR)

(21) Appl. No.: 18/504,201

(22) Filed: Nov. 8, 2023

(30) Foreign Application Priority Data
Jan. 9, 2023 (KR) 10-2023-0002776

(51) Int. Cl. H10K 59/122

(52) U.S. Cl. CPC H10K 59/122

(57) ABSTRACT

A display device includes a pixel defining layer defining a first pixel opening exposing a first pixel electrode and a second pixel opening exposing a second pixel electrode and spaced apart from the first pixel opening, a pattern part disposed on the pixel defining layer between the first pixel opening and the second pixel opening and including a first pattern and a second pattern spaced apart from each other, and a separator including a contact part directly contacting the pixel defining layer between the first pattern and the second pattern, a first inclined part disposed on the contact part, spaced apart from the pattern part to define an undercut space, and having a first average taper angle, and a second inclined part disposed on the first inclined part and having a second average taper angle smaller than the first average taper angle of the first inclined part.

### CROSS REFERENCE TO RELATED APPLICATION(S)

This application claims priority to and benefits of Korean Patent Application No. 10-2023-0002776 under 35 U.S.C. § 119, filed on Jan. 9, 2023, the content of which in its entirety is incorporated herein by reference.

### BACKGROUND

### 1. Technical Field

The disclosure relates to a display device.

### 2. Description of the Related Art

A display device may include a display area displaying an image. The display area may include an emission area defined as an area which emits light, and the emission area may include sub emission areas defined as a minimum unit area which emits light.

Recently, as a degree of integration of a display device increases, a crosstalk phenomenon in which an electrical signal (e.g., electrons, holes, voltage, etc.) is applied from one sub emission area to another sub emission area has become a problem. In case that crosstalk occurs, display performance of the display device may deteriorate.

### SUMMARY

Embodiments provide a display device with improved display performance.

A display device according to an embodiment may include a pixel defining layer defining a first pixel opening exposing a first pixel electrode and a second pixel opening exposing a second pixel electrode and spaced apart from the first pixel opening, a pattern part disposed on the pixel defining layer between the first pixel opening and the second pixel opening and including a first pattern and a second pattern spaced apart from each other, and a separator including a contact part directly contacting the pixel defining layer between the first pattern and the second pattern, a first inclined part disposed on the contact part, spaced apart from the pattern part to define an undercut space, and having a first average taper angle, and a second inclined part disposed on the first inclined part and having a second average taper angle smaller than the first average taper angle of the first inclined part.

In an embodiment, in a cross section, a width of the first inclined part may gradually increase in a direction away from an upper surface of the pixel defining layer, and in the cross section, a width of the second inclined part may gradually increase in a direction away from an upper surface of the pixel defining layer.

In an embodiment, the undercut space defined by the first inclined part may include a first undercut space defined by the first pattern and the first inclined part spaced apart from each other and a second undercut space defined by the second pattern and the first inclined part spaced apart from each other.

In an embodiment, the first pattern may be closer to the first pixel opening than the second pattern, and the second pattern may be closer to the second pixel opening than the first pattern.

In an embodiment, the contact part may cover an entirety of an upper surface of the pixel defining layer between the first pattern and the second pattern spaced apart from each other.

In an embodiment, the display device may further include a first emission layer disposed in the first pixel opening, a second emission layer disposed in the second pixel opening, and a common layer electrically connected to each of the first emission layer and the second emission layer.

In an embodiment, the common layer may include a first portion extending from within the first pixel opening onto the pixel defining layer adjacent to the first pixel opening, a second portion extending from within the second pixel opening onto the pixel defining layer adjacent to the second pixel opening, and a third portion disposed on the separator.

In an embodiment, in an area between the first pixel opening and the second pixel opening, each of the first portion of the common layer and the second portion of the common layer may be spaced apart from the third portion of the common layer.

In an embodiment, in a connection area adjacent to the area between the first pixel opening and the second pixel opening and spaced apart from the separator, each of the first portion of the common layer and the second portion of the common layer may electrically contact the third portion of the common layer.

A display device according to another embodiment may include a pixel defining layer defining a first pixel opening exposing a first pixel electrode and a second pixel opening exposing a second pixel electrode and spaced apart from the first pixel opening and a separator including a contact part directly contacting the pixel defining layer, a first inclined part disposed on the contact part, spaced apart from the pixel defining layer to define an undercut space, and having a first average taper angle, and a second inclined part disposed on the first inclined part and having a second average taper angle smaller than the first average taper angle of the first inclined part.

In an embodiment, in a cross section, a width of the first inclined part may gradually increase in a direction away from an upper surface of the pixel defining layer, and in the cross section, a width of the second inclined part may gradually increase in a direction away from an upper surface of the pixel defining layer.

In an embodiment, the undercut space defined by the first inclined part may include a first undercut space adjacent to the first pixel opening and a second undercut space adjacent to the second pixel opening.

In an embodiment, the display device may further include a first emission layer disposed in the first pixel opening, a second emission layer disposed in the second pixel opening, and a common layer electrically connected to each of the first emission layer and the second emission layer.

In an embodiment, the common layer may include a first portion extending from within the first pixel opening onto the pixel defining layer adjacent to the first pixel opening, a second portion extending from within the second pixel opening onto the pixel defining layer adjacent to the second pixel opening, and a third portion disposed on the separator.

In an embodiment, in an area between the first pixel opening and the second pixel opening, each of the first portion of the common layer and the second portion of the common layer may be spaced apart from the third portion of the common layer.

In an embodiment, in a connection area adjacent to the area between the first pixel opening and the second pixel opening and spaced apart from the separator, each of the first portion of the common layer and the second portion of the common layer may electrically contact the third portion of the common layer.

A display device according to still another embodiment may include a pixel defining layer defining a first pixel opening exposing a first pixel electrode and a second pixel opening exposing a second pixel electrode and spaced apart from the first pixel opening, a pattern part disposed on the pixel defining layer between the first pixel opening and the second pixel opening, and a separator including a first inclined part disposed on the pattern part, spaced apart from the pixel defining layer to define an undercut space, and having a first average taper angle, and a second inclined part disposed on the first inclined part and having a second average taper angle smaller than the first average taper angle of the first inclined part.

In an embodiment, in a cross section, a width of the first inclined part may gradually increase in a direction away from an upper surface of the pixel defining layer, and in the cross section, a width of the second inclined part may gradually increase in a direction away from an upper surface of the pixel defining layer.

In an embodiment, the first inclined part may directly contact the pattern part.

In an embodiment, the undercut space defined by the first inclined part may include a first undercut space adjacent to the first pixel opening and a second undercut space adjacent to the second pixel opening.

In an embodiment, the display device may further include a first emission layer disposed in the first pixel opening, a second emission layer disposed in the second pixel opening, and a common layer electrically connected to each of the first emission layer and the second emission layer.

In an embodiment, the common layer may include a first portion extending from within the first pixel opening onto the pixel defining layer adjacent to the first pixel opening, a second portion extending from within the second pixel opening onto the pixel defining layer adjacent to the second pixel opening, and a third portion disposed on the separator.

In an embodiment, in an area between the first pixel opening and the second pixel opening, each of the first portion of the common layer and the second portion of the common layer may be spaced apart from the third portion of the common layer.

In an embodiment, in a connection area adjacent to the area between the first pixel opening and the second pixel opening and spaced apart from the separator, each of the first portion of the common layer and the second portion of the common layer may electrically contact the third portion of the common layer.

The display device according to embodiments may include a separator disposed on a pixel defining layer between a first pixel opening and a second pixel opening adjacent to the first pixel opening. The separator may disconnect a common layer between the first pixel opening and the second pixel opening, thereby preventing crosstalk from occurring.

It is to be understood that both the foregoing general description and the following detailed description are exemplary and explanatory and are intended to provide further explanation of the invention as claimed.

### BRIEF DESCRIPTION OF THE DRAWINGS

Illustrative, non-limiting embodiments will be more clearly understood from the following detailed description taken in conjunction with the accompanying drawings.

FIG. 1 is a schematic plan view illustrating a display area of a display device according to an embodiment.

FIG. 2 is a schematic cross-sectional view taken along line I-I′ of FIG. 1.

FIG. 3 is a schematic enlarged cross-sectional view of area AA of FIG. 2.

FIG. 4 is a schematic cross-sectional view taken along line II-II′ of FIG. 1.

FIGS. 5 to 11 are schematic views illustrating a method of manufacturing a display device according to an embodiment.

FIG. 12 is a schematic plan view illustrating a display area of a display device according to another embodiment.

FIG. 13 is a schematic cross-sectional view taken along line VI-VI′ of FIG. 12.

FIG. 14 is a schematic enlarged cross-sectional view of area BB of FIG. 13.

FIGS. 15 to 17 are schematic views illustrating a method of manufacturing a display device according to another embodiment.

FIG. 18 is a schematic plan view illustrating a display area of a display device according to another embodiment.

FIG. 19 is a schematic cross-sectional view taken along line VIII-VIII′ of FIG. 18.

FIG. 20 is a schematic enlarged cross-sectional view of area CC of FIG. 19.

FIGS. 21 to 28 are schematic views illustrating a method of manufacturing a display device according to embodiment.

### DETAILED DESCRIPTION OF THE EMBODIMENTS

The disclosure now will be described more fully hereinafter with reference to the accompanying drawings, in which various embodiments are shown. This disclosure may however, be embodied in many different forms, and should not be construed as limited to the embodiments set forth herein. Rather, these embodiments are provided so that this disclosure will be more thorough and complete, and will convey the scope of the disclosure to those skilled in the art. Like reference numerals and/or reference characters refer to like elements throughout.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

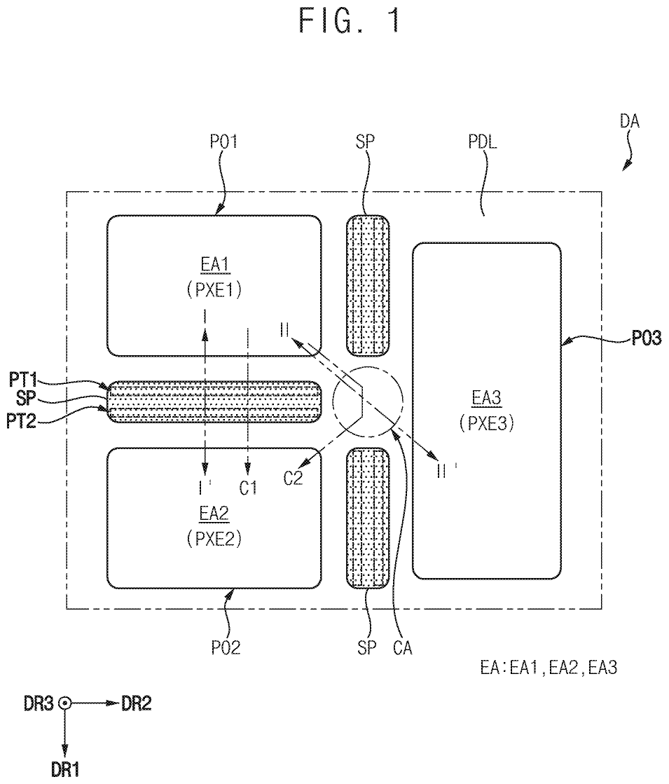

FIG. 1 is a schematic plan view illustrating a display area of a display device according to an embodiment.

Referring to FIG. 1, a display device according to an embodiment may include a pixel defining layer PDL, a separator SP, a first pattern PT1, and a second pattern PT2 disposed in a display area DA.

The pixel defining layer PDL may define first to third pixel openings PO1, PO2, and PO3. The first to third pixel openings PO1, PO2, and PO3 may expose at least a portion of first to third pixel electrodes PXE1, PXE2, and PXE3 referred to as anode electrodes (or cathode electrodes). In this case, the first to third pixel openings PO1, PO2, and PO3 may define an emission area EA.

The emission area EA may be an area corresponding to the first to third pixel openings PO1, PO2, and PO3 and may be an area that substantially emits light. For example, light may be emitted from an organic light emitting material disposed in the emission area EA.

The emission area EA may include sub emission areas. For example, the emission area EA may include a first sub emission area EA1, a second sub emission area EA2, and a third sub emission area EA3. In this case, in an embodiment, the first sub emission area EA1, the second sub emission area EA2, and the third sub emission area EA3 may be areas emitting light of different colors. As another example, in another embodiment, the first sub emission area EA1, the second sub emission area EA2, and the third sub emission area EA3 may emit light of substantially same color as each other.

The first sub emission area EA1, the second sub emission area EA2, and the third sub emission area EA3 may have various arrangements within the display area DA. For example, the second sub emission area EA2 may be spaced apart from the first sub emission area EA1 in the first direction DR1, and the third sub emission area EA3 may be spaced apart from the first sub emission area EA1 and the second sub emission area EA2 in a second direction DR2 crossing the first direction DR1.

The separator SP may be disposed on the pixel defining layer PDL between two adjacent emission areas. In this case, the separator SP may be positioned to overlap a line connecting the shortest distance on a plane between the two adjacent emission areas. For example, the separator SP may be disposed to overlap a first path C1 defined as the shortest path on a plane between the first sub emission area EA1 and the second sub emission area EA2.

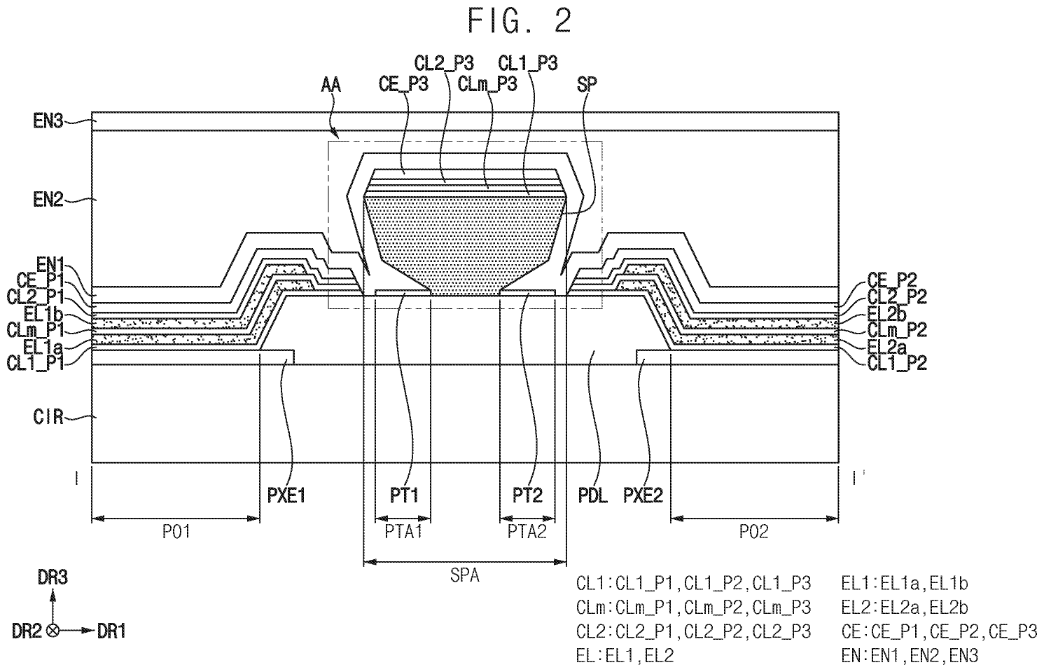

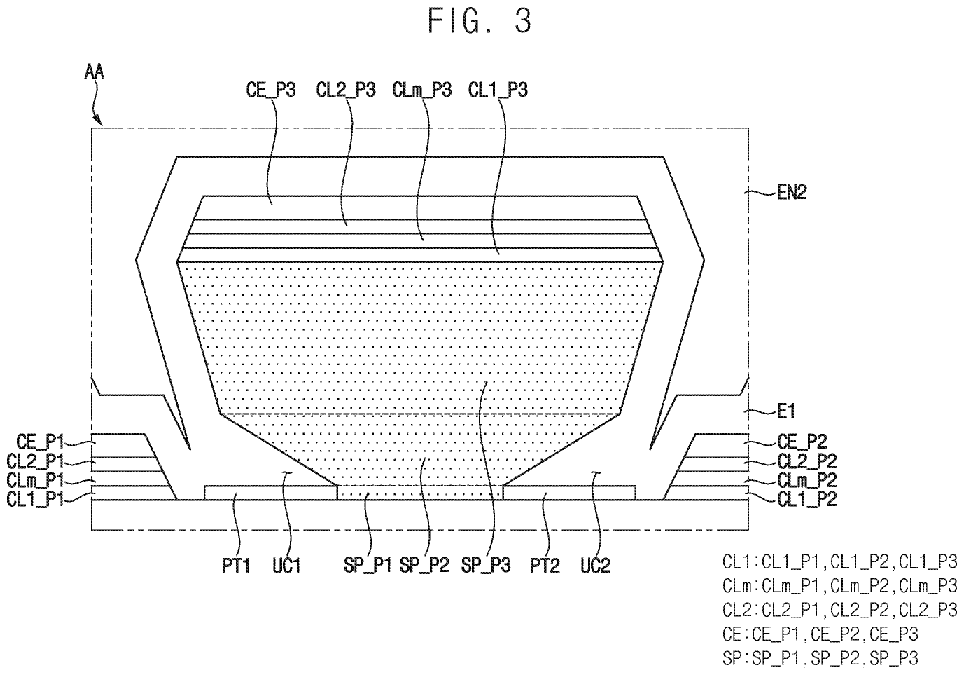

The first pattern PT1 and the second pattern PT2 may be disposed on the pixel defining layer PDL and may overlap at least a portion of the separator SP. The first pattern PT1 and the second pattern PT2 will be described below in detail with reference to FIGS. 2 and 3.

A connection area CA may be a partial area on the pixel defining layer PDL spaced apart from the separator SP. The connection area CA may not overlap a line connecting the shortest distance on a plane between the two adjacent emission areas. For example, the connection area CA may not overlap the first path C1 which is the shortest distance between the first sub emission area EA1 and the second sub emission area EA2 on a plane. In this case, a length of a second path C2 defined as a path starting from the first sub emission area EA1 and arriving at the second sub emission area EA2 via an arbitrary point in the connection area CA may be longer than a length of the first path C1.

FIG. 2 is a schematic cross-sectional view taken along line I-I′ of FIG. 1. FIG. 3 is a schematic enlarged cross-sectional view of area AA of FIG. 2.

Referring to FIGS. 1 to 3, a display device according to an embodiment may include a circuit layer CIR, the first pixel electrode PXE1, the second pixel electrode PXE2, a pixel defining layer PDL, the first pattern PT1, the second pattern PT2, an organic light emitting material EL, a first functional layer CL1, an intermediate functional layer CLm, a second functional layer CL2, a common electrode layer CE, the separator SP, and/or an encapsulation layer EN. In this case, the first functional layer CL1, the intermediate functional layer CLm, the second functional layer CL2, and the common electrode layer CE may be referred to as a common layer. The common layer may be a layer entirely formed by a front deposition process or the like.

The circuit layer CIR may include transistors and capacitors. For example, the circuit layer CIR may include a first driving transistor electrically connected to the first pixel electrode PXE1 and a second driving transistor electrically connected to the second pixel electrode PXE2.

The first pixel electrode PXE1 and the second pixel electrode PXE2 may be disposed on the circuit layer CIR. The first pixel electrode PXE1 and the second pixel electrode PXE2 may be spaced apart from each other. In an embodiment, each of the first pixel electrode PXE1 and the second pixel electrode PXE2 may be referred to as an anode electrode (or cathode electrode).

The pixel defining layer PDL may be disposed on the circuit layer CIR. The pixel defining layer PDL may define a first pixel opening PO1 exposing the first pixel electrode PXE1 and a second pixel opening PO2 exposing the second pixel electrode PXE2 and spaced apart from the first pixel opening PO1.

The first pattern PT1 and the second pattern PT2 may be disposed on the pixel defining layer PDL between the first and second pixel openings PO1 and PO2. The first pattern PT1 may be disposed closer to the first pixel opening PO1 than the second pattern PT2. The second pattern PT2 may be disposed closer to the second pixel opening PO2 than the first pattern PT1. In this case, the first pattern PT1 and the second pattern PT2 may be spaced apart from each other.

An area where the first pattern PT1 is disposed may be referred to as a first pattern area PTA1, and an area where the second pattern PT2 is disposed may be referred to as a second pattern area PTA2.

The separator SP may be disposed on the pixel defining layer PDL between the first pixel opening PO1 and the second pixel opening PO2. In this case, an area where the separator SP is disposed may be referred to as a separation area SPA.

The separator SP may include parts sequentially arranged in a thickness direction of the pixel defining layer (e.g., a third direction DR3) perpendicular to the first and second directions DR1 and DR2. More specifically, the separator SP may include a contact part SP_P1 disposed on the pixel defining layer PDL, a first inclined part SP_P2 disposed on the contact part SP_P1, and a second inclined part SP_P3 disposed on the first inclined part SP_P2. In this case, the contact part SP_P1, the first inclined part SP_P2, and the second inclined part SP_P3 may be integrally formed or may be integral with each other.

The contact part SP_P1 may be disposed between the first pattern PT1 and the second pattern PT2 and may directly contact the pixel defining layer PDL. In this case, as shown in FIG. 3, the contact part SP_P1 may cover the entirety of an upper surface of the pixel defining layer PDL between the first pattern PT1 and the second pattern PT2.

A width of the first inclined part SP_P2 may gradually increase in the third direction DR3. In other words, the first inclined part SP_P2 may have a reverse taper shape with respect to the upper surface of the pixel defining layer PDL.

The first inclined part SP_P2 may be spaced apart from each of the first pattern part PT1 and the second pattern part PT2 to define an undercut space. In this case, the undercut space defined by the first pattern part PT1 and the first inclined part SP_P2 spaced apart from each other may be referred to as a first undercut space UC1, and the undercut space defined by the first inclined part SP_P2 and the second pattern part PT2 spaced apart from each other may be referred to as a second undercut space UC2.

A width of the second inclined part SP_P3 may gradually increase in the third direction DR3. In other words, the second inclined part SP_P3 may have a reverse taper shape with respect to the upper surface of the pixel defining layer PDL.

The first inclined part SP_P2 may have a first average taper angle, and the second inclined part SP_P3 may have a second average taper angle. The first average taper angle may refer to an average inclination degree of a side surface of the first inclined part SP_P2 with respect to the third direction DR3, and the second average taper angle may refer to an average inclination degree of a side surface of the second inclined part SP_P3 with respect to the third direction DR3. In an embodiment, the second average taper angle may be smaller than the first average taper angle. In another embodiment, the second average taper angle may be equal to or greater than the first average taper angle.

The organic light emitting material EL may include a first organic light emitting material EL1 and a second organic light emitting material EL2. The first organic light emitting material EL1 may be disposed on the first pixel electrode PXE1 within the first pixel opening PO1. The second organic light emitting material EL2 may be disposed on the second pixel electrode PXE2 within the second pixel opening PO2.

The first organic light emitting material EL1 may include a first lower light emitting material EL1a and a first upper light emitting material EL1b disposed on the first lower light emitting material EL1a. In an embodiment, the first lower light emitting material EL1a and the first upper light emitting material EL1b may emit light of substantially same color. In another embodiment, the first lower light emitting material EL1a and the first upper light emitting material EL1b may emit light of different colors.

The second organic light emitting material EL2 may include a second lower light emitting material EL2a and a second upper light emitting material EL2b disposed on the second lower light emitting material EL2a. In an embodiment, the second lower light emitting material EL2a and the second upper light emitting material EL2b may emit light of substantially same color. In another embodiment, the second lower light emitting material EL2a and the second upper light emitting material EL2b may emit light of different colors.

The first functional layer CL1 may include at least one layer for improving light emitting efficiency of the organic light emitting material EL. For example, the first functional layer CL1 may include at least one of a hole injection layer and a hole transport layer.

The first functional layer CL1 may be disconnected between the first pixel opening PO1 and the second pixel opening PO2 by the separator SP. More specifically, the first functional layer CL1 may include a first portion CL1_P1, a second portion CL1_P2, and a third portion CL1_P3, and each of the first portion CL1_P1 of the first functional layer CL1 and the second portion CL1_P2 of the first functional layer CL1 may be spaced apart from the third portion CL1_P3 of the first functional layer CL1 by the separator SP.

The first portion CL1_P1 of the first functional layer CL1 may be disposed between the first lower light emitting material EL1a and the first pixel electrode PXE1 in the first pixel opening PO1. The first portion CL1_P1 of the first functional layer CL1 may extend from within the first pixel opening PO1 and be disposed on the upper surface of the pixel defining layer PDL adjacent to the first pixel opening PO1.

The second portion CL1_P2 of the first functional layer CL1 may be disposed between the second lower light emitting material EL2a and the second pixel electrode PXE2 in the second pixel opening PO2. The second portion CL1_P2 of the first functional layer CL1 may extend from within the second pixel opening PO2 and be disposed on the upper surface of the pixel defining layer PDL adjacent to the second pixel opening PO2.

The third portion CL1_P3 of the first functional layer CL1 may be disposed on the separator SP. Accordingly, the third portion CL1_P3 of the first functional layer CL1 may be spaced apart from each of the first portion CL1_P1 of the first functional layer CL1 and the second portion CL1_P2 of the first functional layer CL1 by the separator SP.

The intermediate functional layer CLm may include at least one layer for improving light emitting efficiency of the organic light emitting material EL. For example, the intermediate functional layer CLm may include an n-type charge generation layer and a p-type charge generation layer disposed on the n-type charge generation layer.

The intermediate functional layer CLm may be disconnected between the first pixel opening PO1 and the second pixel opening PO2 by the separator SP. More specifically, the intermediate functional layer CLm may include a first portion CLm_P1, a second portion CLm_P2, and a third portion CLm_P3, and each of the first portion CLm_P1 of the intermediate functional layer CLm and the second portion CLm_P2 of the intermediate functional layer CLm may be spaced apart from the third portion CLm_P3 of the intermediate functional layer CLm by the separator SP.

The first portion CLm_P1 of the intermediate functional layer CLm may be disposed between the first lower light emitting material EL1a and the first upper light emitting material EL1b within the first pixel opening PO1. The first portion CLm_P1 of the intermediate functional layer CLm may extend from within the first pixel opening PO1 and be disposed on the upper surface of the pixel defining layer PDL adjacent to the first pixel opening PO1.

The second portion CLm_P2 of the intermediate functional layer CLm may be disposed between the second lower light emitting material EL2a and the second upper light emitting material EL2b within the second pixel opening PO2. The second portion CLm_P2 of the intermediate functional layer CLm may extend from within the second pixel opening PO2 and may be disposed on the upper surface of the pixel defining layer PDL adjacent to the second pixel opening PO2.

The third portion CLm_P3 of the intermediate functional layer CLm may be disposed on the separator SP. Accordingly, the third portion CLm_P3 of the intermediate functional layer CLm may be separated from the first portion CLm_P1 of the intermediate functional layer CLm and the second portion CLm_P2 of the intermediate functional layer CLm by the separator SP.

The second functional layer CL2 may include at least one layer for improving light emitting efficiency of the organic light emitting material EL. For example, the second functional layer CL2 may include at least one of an electron injection layer and an electron transport layer.

The second functional layer CL2 may be disconnected between the first pixel opening PO1 and the second pixel opening PO2 by the separator SP. More specifically, the second functional layer CL2 may include a first portion CL2_P1, a second portion CL2_P2, and a third portion CL2_P3, and each of the first portion CL2_P1 of the second functional layer CL2 and the second portion CL2_P2 of the second functional layer CL2 may be spaced apart from the third portion CL2_P3 of the second functional layer CL2 by the separator SP.

The first portion CL2_P1 of the second functional layer CL2 may be disposed on the first upper light emitting material EL1b within the first pixel opening PO1. The first portion CL2_P1 of the second functional layer CL2 may extend from within the first pixel opening PO1 and may be disposed on the upper surface of the pixel defining layer PDL adjacent to the first pixel opening PO1.

The second portion CL2_P2 of the second functional layer CL2 may be disposed on the second upper light emitting material EL2b within the second pixel opening PO2. The second portion CL2_P2 of the second functional layer CL2 may extend from within the second pixel opening PO2 and may be disposed on the upper surface of the pixel defining layer PDL adjacent to the second pixel opening PO2.

The third portion CL2_P3 of the second functional layer CL2 may be disposed on the separator SP. Accordingly, the third portion CL2_P3 of the second functional layer CL2 may be spaced apart from each of the first portion CL2_P1 of the second functional layer CL2 and the second portion CL2_P2 of the second functional layer CL2 by the separator SP.

The common electrode layer CE may be disposed on the organic light emitting material EL. In this case, in an embodiment, the common electrode layer CE may be referred to as a cathode electrode (or an anode electrode).

The common electrode layer CE may be disconnected between the first pixel opening PO1 and the second pixel opening PO2 by the separator SP. More specifically, the common electrode layer CE may include a first portion CE_P1, a second portion CE_P2, and a third portion CE_P3, and each of the first portion CE_P1 of the common electrode layer CE and the second portion CE_P2 of the common electrode layer CE may be spaced apart from the third portion CE_P3 of the common electrode layer CE by a separator SP.

The first portion CE_P1 of the common electrode layer CE may be disposed on the first organic light emitting material EL1 within the first pixel opening PO1. The first portion CE_P1 of the common electrode layer CE may extend from within the first pixel opening PO1 and be disposed on the upper surface of the pixel defining layer PDL adjacent to the first pixel opening PO1.

The second portion CE_P2 of the common electrode layer CE may be disposed on the second organic light emitting material EL2 within the second pixel opening PO2. The second portion CE_P2 of the common electrode layer CE may extend from within the second pixel opening PO2 and be disposed on the upper surface of the pixel defining layer PDL adjacent to the second pixel opening PO2.

The third portion CE_P3 of the common electrode layer CE may be disposed on the separator SP. Accordingly, the third portion CE_P3 of the common electrode layer CE may be spaced apart from the first portion CE_P1 of the common electrode layer CE and the second portion CE_P2 of the common electrode layer CE by the separator SP.

The encapsulation layer EN may be disposed on the common electrode layer CE. The encapsulation layer EN may entirely cover the common electrode layer CE, the separator layer SP, the pixel defining layer PDL, the first pattern PT1 and the second pattern PT2. In an embodiment, the encapsulation layer EN may include a first inorganic encapsulation layer EN1 including an inorganic insulating material, an organic encapsulation layer EN2 disposed on the first inorganic encapsulation layer EN1 and including an organic insulating material, and a second inorganic encapsulation layer EN3 disposed on the organic encapsulation layer EN2 and including an inorganic insulating material.

In the disclosure, the separator SP may include a second inclined part SP_P3 having a reverse taper shape. Accordingly, in case that each of the first functional layer CL1, the intermediate functional layer CLm, the second functional layer CL2, and the common electrode layer CE is entirely formed by a front deposition process or the like, the first functional layer CL1, the intermediate functional layer CLm, the second functional layer CL2, and the common electrode layer CE may not be substantially formed on a side surface of the second inclined part SP_P3. Therefore, the first functional layer CL1, the intermediate functional layer CLm, the second functional layer CL2, and the common electrode layer CE may be disconnected by the second inclined part SP_P3.

In this case, the first functional layer CL1, the intermediate functional layer CLm, the second functional layer CL2 and the common electrode layer CE may be formed on a side surface of the second inclined part SP_P3 due to a process error, etc., and thus there may be a problem of the first functional layer CL1, the intermediate functional layer CLm, the second functional layer CL2, and the common electrode layer CE not being disconnected. To prevent this, in the disclosure, the separator SP may include the first inclined part SP_P2 having the first average taper angle greater than the second average taper angle of the second inclined part SP_P3. Accordingly, even if the first functional layer CL1, the intermediate functional layer CLm, the second functional layer CL2, and the common electrode layer CE are formed on the side surface of the second inclined part SP_P3 due to a process error, etc., the first functional layer CL1, the intermediate functional layer CLm, the second functional layer CL2, and the common electrode layer CE may not be formed on the side surface of the first inclined part SP_P2 (or within the first undercut space UC1 and the second undercut space UC2). For example, even in case that the first functional layer CL1, the intermediate functional layer CLm, the second functional layer CL2, and the common electrode layer CE are formed on the side surface of the second inclined part SP_P3, the first functional layer CL1, the intermediate functional layer CLm, the second functional layer CL2, and the common electrode layer CE may be disconnected by the first inclination part SP_P1.

As described above, in the disclosure, the common layer may be disconnected by the separator SP formed in the separation area SPA. Accordingly, electrical signals (e.g., electrons, holes, voltage, etc.) applied to the first path C1 through the common layer may be blocked, and a crosstalk phenomenon between adjacent sub emission areas may be prevented from occurring.

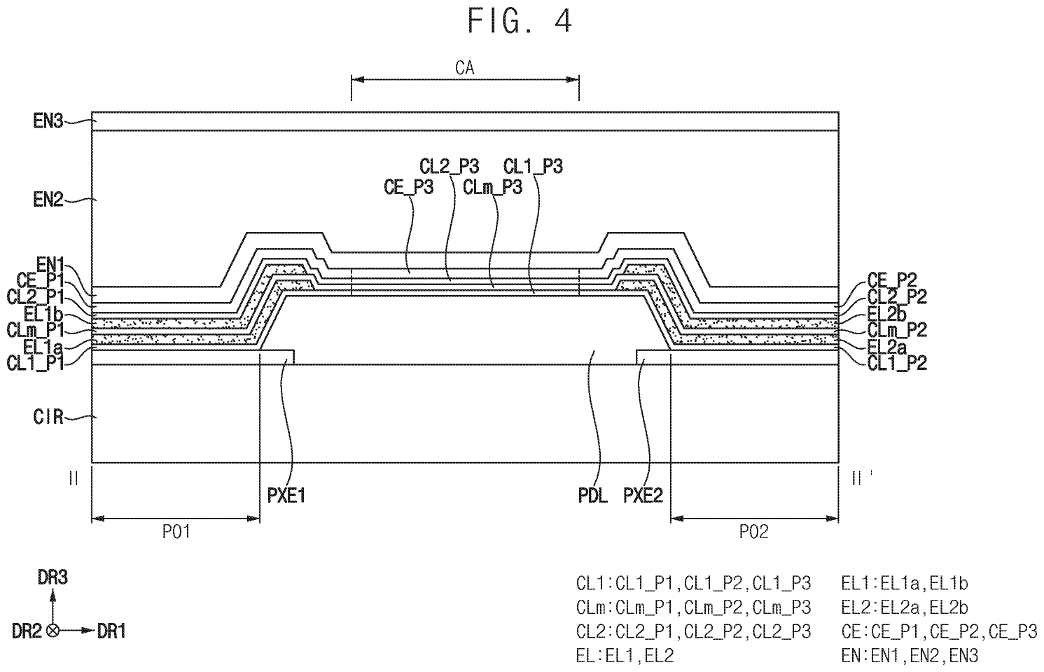

FIG. 4 is a schematic cross-sectional view taken along line II-II′ of FIG. 1.

Referring to FIGS. 1 and 4, the separator SP may not be disposed in the connection area CA. Accordingly, each of the first functional layer CL1, the intermediate functional layer CLm, the second functional layer CL2, and the common electrode layer CE may not be disconnected in the common area CA.

For example, referring to the common electrode layer CE, the third portion CE_P3 of the common electrode layer CE may electrically contact the first portion CE_P1 of the common electrode layer CE and the second portion CE_P2 of the common electrode layer CE in the connection area CA.

Accordingly, the first portion CE_P1 of the common electrode layer CE and the second portion CE_P2 of the common electrode layer CE may be applied with a same electrical signal through the third portion CE_P3 of the common electrode layer CE disposed in the connection area CA. In this case, as described above with reference to FIG. 1, since the length of the second path C2 passing through an arbitrary point in the connection area CA is greater than the length of the first path C1, a crosstalk may not substantially occur between the first sub emission area EA1 and the second sub emission area EA2 by the electric signal applied to the second path C2 through the common electrode layer CE.

Similarly, each of the first portion CL1_P1 of the first functional layer CL1 and the second portion CL1_P2 of the first functional layer CL1 may electrically contact the third portion CL1_P3 of the first functional layer CL1 in the connection area CA, each of the first portion CLm_P1 of the intermediate functional layer CLm and the second portion CLm_P2 of the intermediate functional layer CLm may electrically contact the third portion CLm_P3 of the intermediate functional layer CLm in the connection area CA, and each of the first portion CL2_P1 of the second functional layer CL2 and the second portion CL2_P2 of the second functional layer CL2 may electrically contact the third portion CL2_P3 of the second functional layer CL2 in the connection area CA.

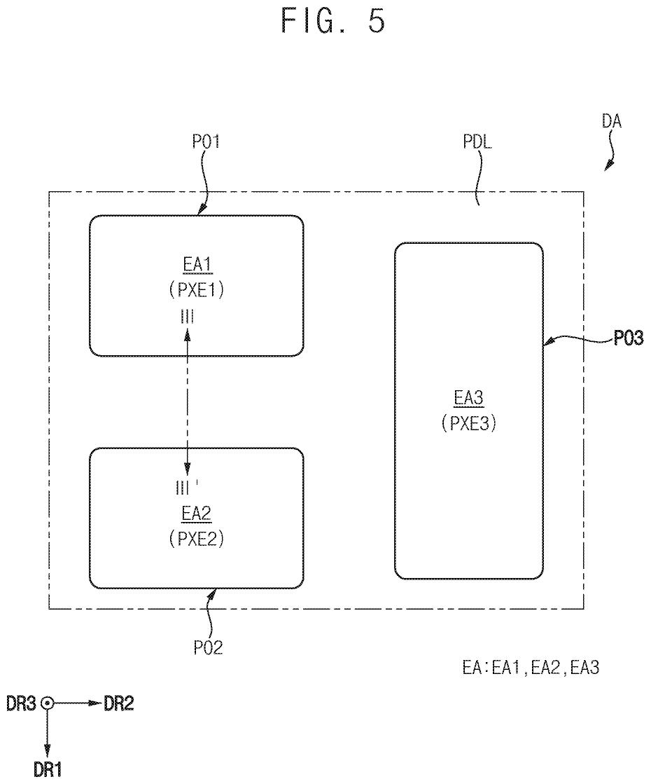

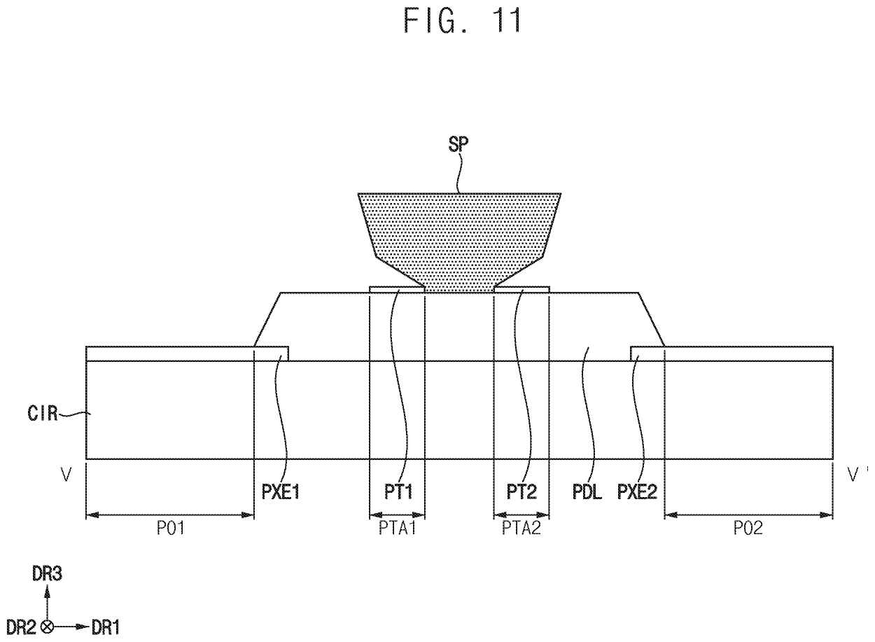

FIGS. 5 to 11 are schematic views illustrating a method of manufacturing a display device according to an embodiment.

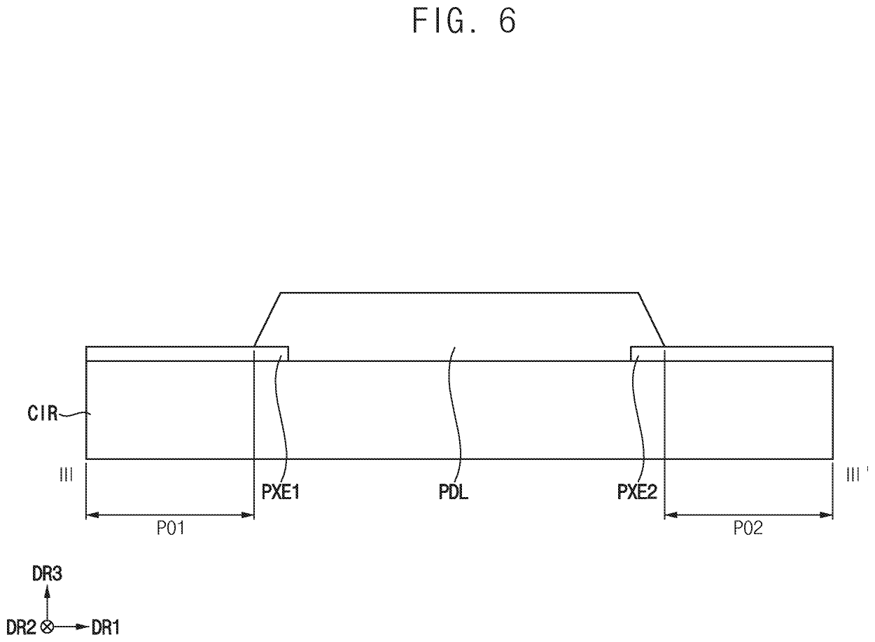

Referring to FIGS. 5 and 6, pixel electrodes spaced apart from each other may be formed on the circuit layer CIR. For example, the first pixel electrode PXE1 and the second pixel electrode PXE2 may be formed on the circuit layer CIR.

The pixel defining layer PDL may be formed on the circuit layer CIR to expose the pixel electrodes and define pixel openings spaced apart from each other. For example, the pixel defining layer PDL may define the first pixel opening PO1 exposing the first pixel electrode PXE1, the second pixel opening PO2 exposing the second pixel electrode PXE2, and the third pixel opening PO3 exposing the third pixel electrode PXE3.

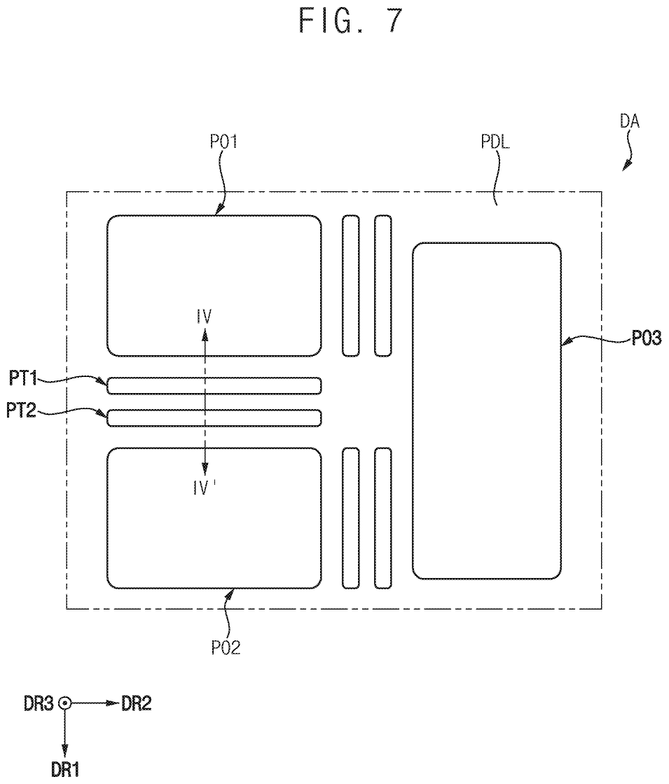

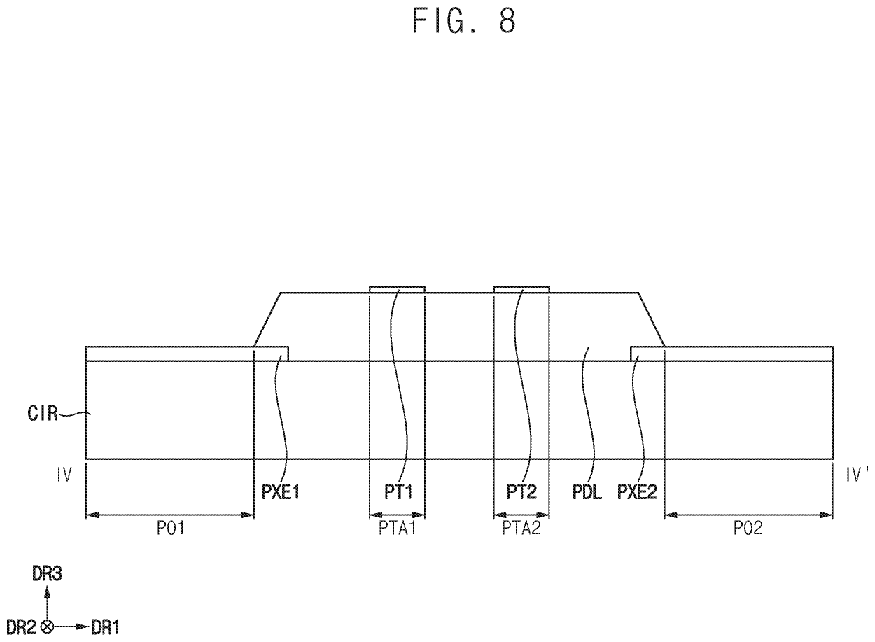

Referring to FIGS. 7 and 8, the pattern part including the first pattern PT1 and the second pattern PT2 may be formed on the pixel defining layer PDL. The pattern part may be formed between two adjacent pixel openings. For example, the first pattern PT1 and the second pattern PT2 may be positioned between the first pixel opening PO1 and the second pixel opening PO2. Also, the first pattern PT1 may be closer to the first pixel opening PO1 than the second pattern PT2, and the second pattern PT2 may be closer to the second pixel opening PO2 than the first pattern PT1.

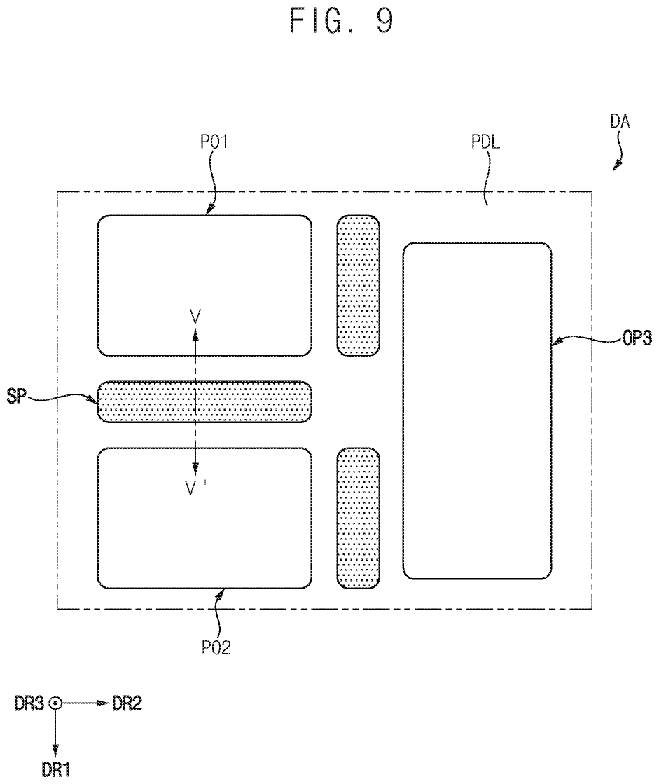

Referring to FIGS. 9 to 11, the separator SP may be formed on the pixel defining layer PDL.

The separator SP may be formed by coating a photoresist layer PR on the display area DA entirely and exposing and developing the photoresist layer PR.

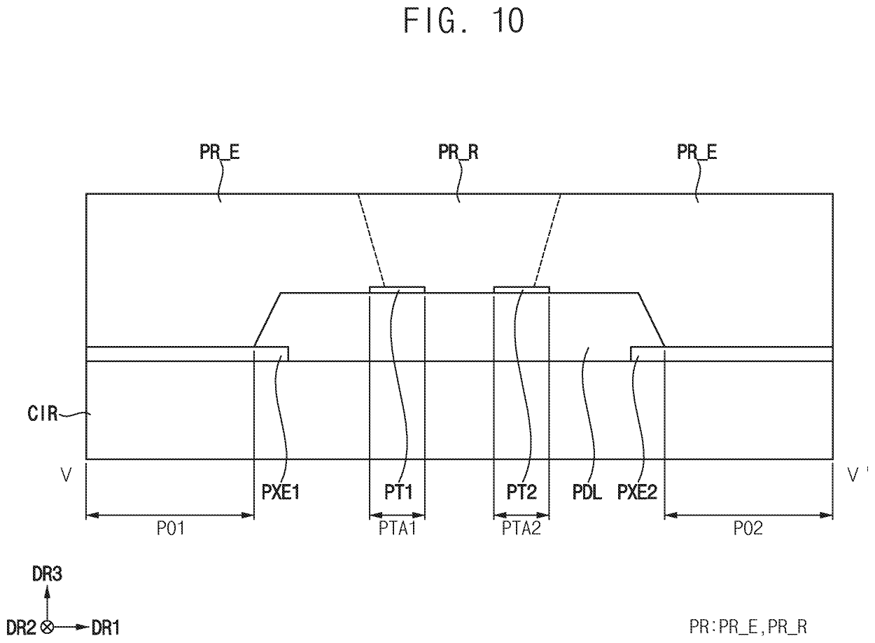

More specifically, the photoresist layer PR may be entirely coated on the display area DA. In this case, as shown in FIG. 10, the photoresist layer PR may entirely cover the pixel defining layer PDL, the first pixel electrode PXE1, the second pixel electrode PXE2, the first pattern PT1 and the second pattern PT2.

After the photoresist layer PR is coated, a portion of the photoresist layer PR may be exposed to form a removed portion PR_E and a remaining portion PR_R. In case that the photoresist layer PR is a positive type, the removed portion PR_E may be exposed, and thus, the removed portion PR_E may be removed in a developing process to be described below. As another example, in case that the photoresist layer PR is a negative type, the remaining portion PR_R may be exposed, and thus, the removed portion PR_E excluding the remaining portion PR_R may be removed in a developing process described below.

After exposing the photoresist layer PR, the removed portion PR_E may be removed by developing the photoresist layer PR with a developing solution. In this case, the developing solution may penetrate into an interface between the remaining portion PR_R and the first pattern PT1 and an interface between the remaining portion PR_R and the second pattern PT2. Accordingly, the separator SP may be formed to define the first undercut space UC1 and the second undercut space UC2 described above with reference to FIG. 3 and may be disposed in the separation area SPA.

As described above, the first undercut space UC1 and the second undercut space UC2 may be formed by interfacial penetration of the developing solution. To this end, each of the first pattern PT1 and the second pattern PT2 may include a material having relatively weak adhesive strength to a material included in the separator SP (e.g., a material included in the photoresist layer PR). For example, the separator SP may include a photosensitive organic material, and the photosensitive organic material may have hydrophobic properties. In this case, the first pattern PT1 and the second pattern PT2 may include a hydrophilic material (e.g., metal, metal oxide, inorganic insulating material, etc.), and thus interfacial penetration of the developing solution may be facilitated.

In this case, by adjusting the width of the first pattern PT1 in the first direction DR1 and the width of the second pattern PT2 in the first direction DR1, the width of the first undercut space UC1 in the first direction DR1 and the width of the second undercut space UC2 in the first direction DR1 may be adjusted. Similarly, the first average taper angle of the first inclined part SP_P2 of the separator SP may be adjusted by changing a forming condition of each of the first pattern PT1 and the second pattern PT2.

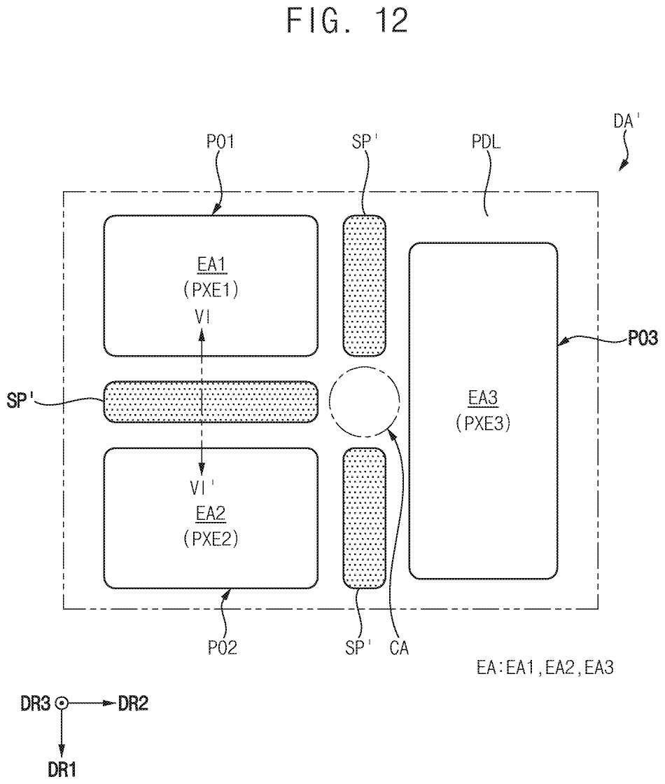

FIG. 12 is a schematic plan view illustrating a display area of a display device according to another embodiment.

Referring to FIG. 12, a display device according to another embodiment may include a pixel defining layer PDL and a separator SP′ disposed in a display area DA′.

The pixel defining layer PDL may be substantially same as the pixel defining layer PDL described with reference to FIG. 1. For example, the pixel defining layer PDL may define the first to third pixel openings PO1, PO2, and PO3 exposing at least a portion of the first to third pixel electrodes PXE1, PXE2, and PXE3, respectively and the first to third pixel openings PO1, PO2, and PO3 may define the emission area EA.

The separation layer SP′ may be disposed on the pixel defining layer PDL between two adjacent emission areas. In this case, the separator SP' may be disposed overlapping a line connecting the shortest distance on a plane between the adjacent two emission areas.

The connection area CA may be a partial area on the pixel defining layer PDL spaced apart from the separator SP′. The connection area CA may be substantially same as (or similar to) the connection area CA described with reference to FIGS. 1 and 4.

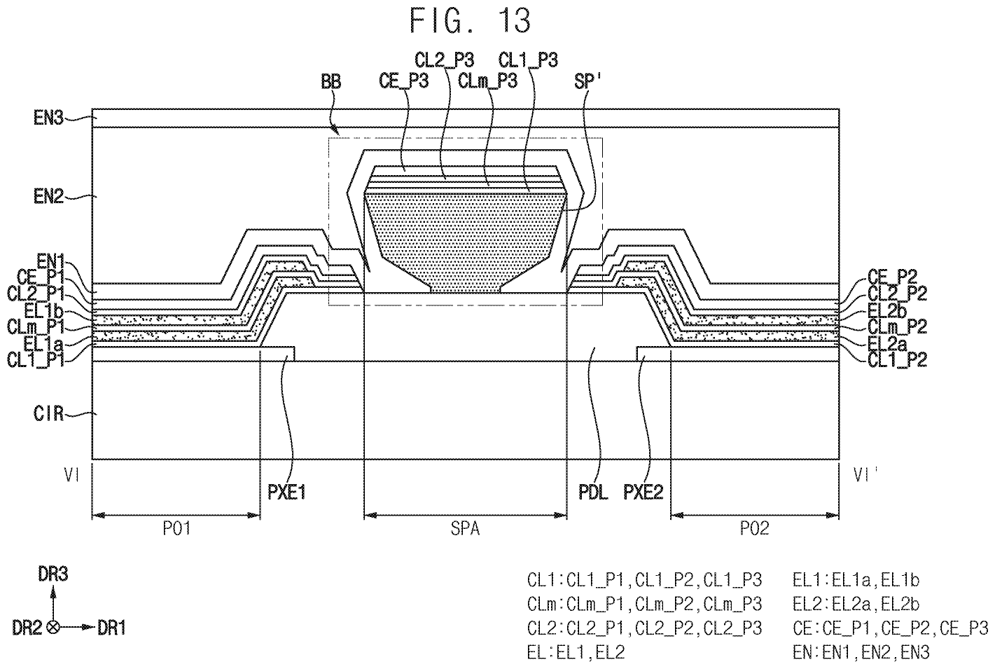

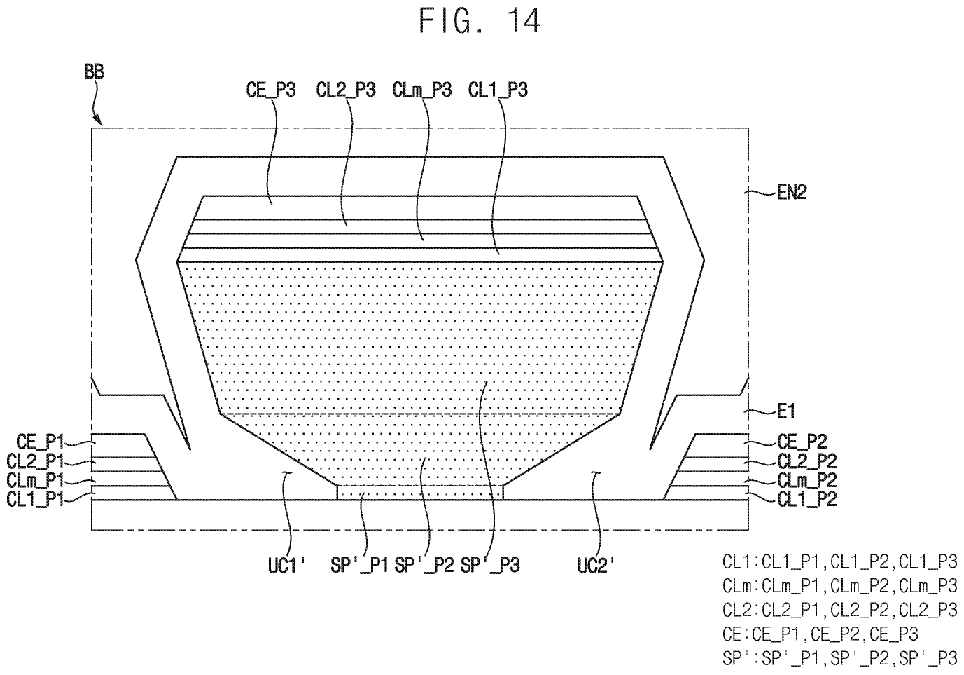

FIG. 13 is a schematic cross-sectional view taken along line VI-VI′ of FIG. 12. FIG. 14 is a schematic enlarged cross-sectional view of area BB of FIG. 13.

Referring to FIGS. 12 to 14, a display device according to another embodiment may include a circuit layer CIR, a first pixel electrode PXE1, a second pixel electrode PXE2, a pixel defining layer PDL, an organic light emitting material EL, a first functional layer CL1, an intermediate functional layer CLm, a second functional layer CL2, a common electrode layer CE, a separator SP′, and/or an encapsulation layer EN.

In this case, the circuit layer CIR, the first pixel electrode PXE1, the second pixel electrode PXE2, the pixel defining layer PDL, the organic light emitting material EL, the first functional layer CL1, the intermediate functional layer CLm, the second functional layer CL2, the common electrode layer CE, the encapsulation layer EN according to another embodiment may be substantially same as (or similar to) the circuit layer CIR, the first pixel electrode PXE1, the second pixel electrode PXE2, the pixel defining layer PDL, the organic light emitting material EL, the first functional layer CL1, the intermediate functional layer CLm, the second functional layer CL2, the common electrode layer CE, the encapsulation layer EN described with reference to FIGS. 1 and 4. Therefore, descriptions of repetitive contents are omitted.

Compared to the display device according to an embodiment described with reference to FIGS. 1 to 4, the display device according to another embodiment may not include the first pattern PT1 and the second pattern PT2.

Accordingly, in the separator SP′ including a contact part SP′_P1, a first inclined part SP′_P2 disposed on the contact part SP′_P1, and a second inclined part SP′_P3 disposed on the first inclined part SP′_P2, a first undercut space UC1′ may be defined as a separation space between the first inclined part SP′_P2 and the pixel defining layer PDL, and a second undercut space UC2′ may be defined as a separation space between the first inclined part SP′_P2 and the pixel defining layer PDL. In this case, except for the first undercut space UC1′ and the second undercut space UC2′, the shape and function of each of the contact part SP′_P1, the first inclined part SP′_P2, and the second inclined part SP′_P3 may be substantially same as (or similar to) the shape and function of each of the contact part SP_P1, the first inclined part SP_P2, and the second inclined part SP_P3 described with reference to FIGS. 1 to 4. Therefore, descriptions of repetitive contents are omitted.

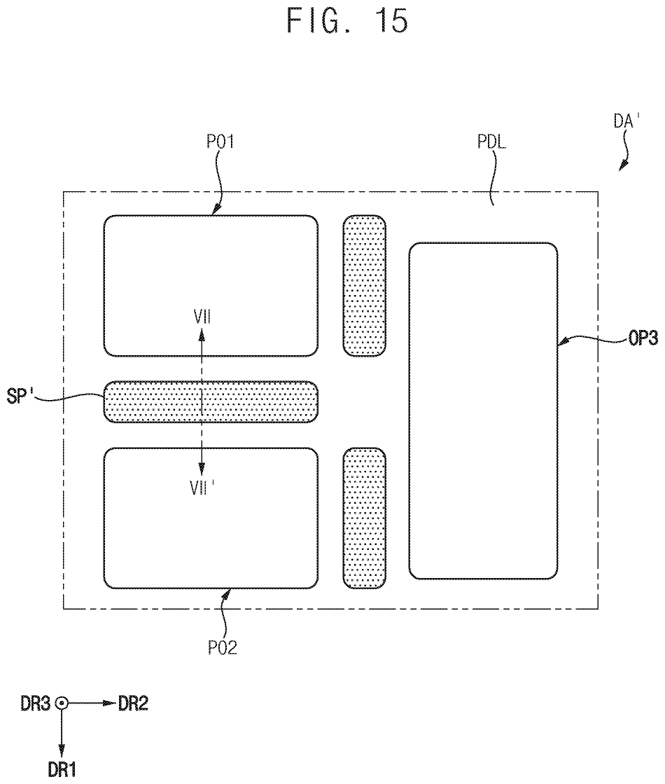

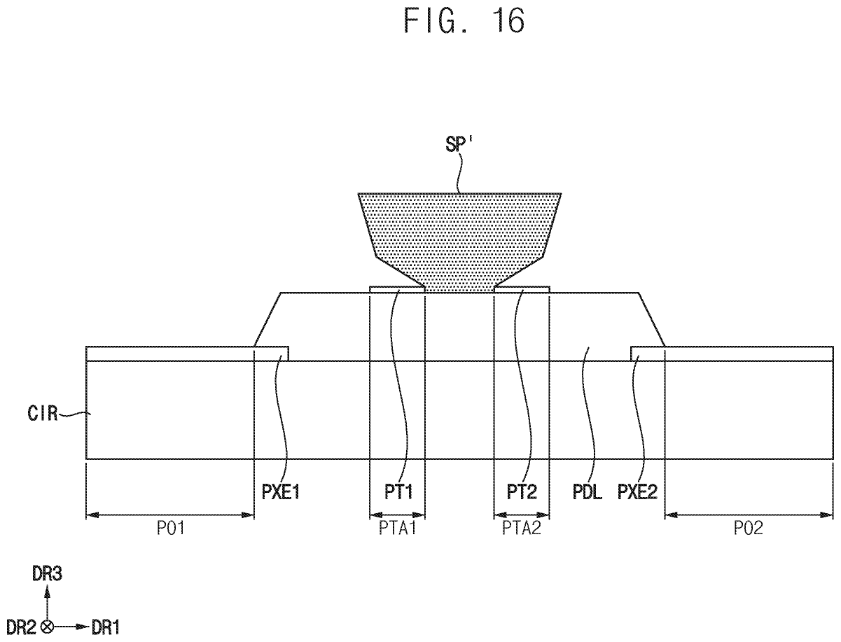

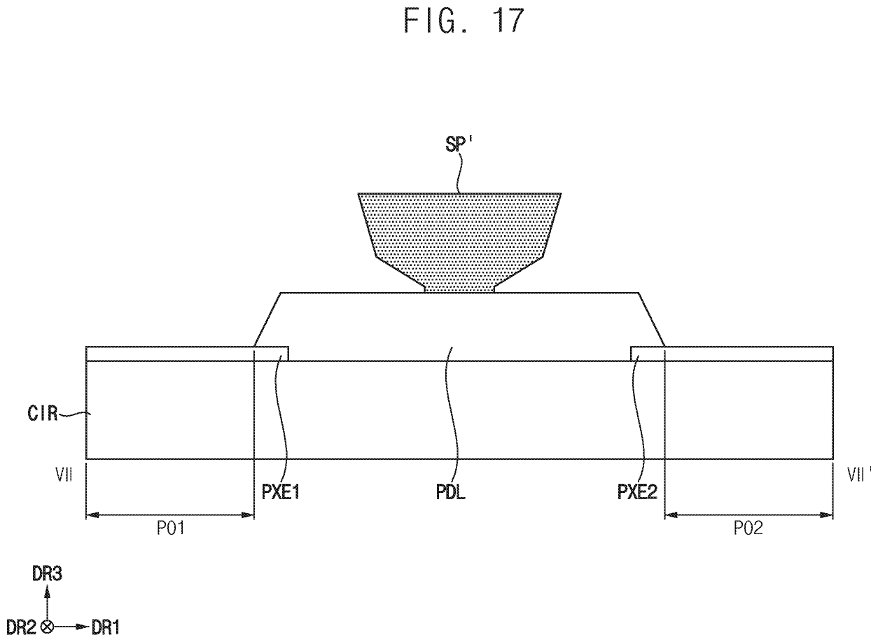

FIGS. 15 to 17 are schematic views illustrating a method of manufacturing a display device according to another embodiment.

Referring to FIGS. 15 to 17, after forming the circuit layer CIR, the first pixel electrode PXE1, the second pixel electrode PXE2, the pixel defining layer PDL, the first pattern PT1, the second pattern PT2, and the separator SP′, the first pattern PT1 and the second pattern PT2 may be removed.

In this case, a method of forming the circuit layer CIR, the first pixel electrode PXE1, the second pixel electrode PXE2, the pixel defining layer PDL, the first pattern PT1, the second pattern PT2, and the separator SP′ may be substantially same as (or similar to) a method of forming the circuit layer CIR, the first pixel electrode PXE1, the second pixel electrode PXE2, the pixel defining layer PDL, the first pattern PT1, the second pattern PT2, and the separator SP described with reference to FIGS. 5 to 12. Therefore, descriptions of repetitive contents are omitted.

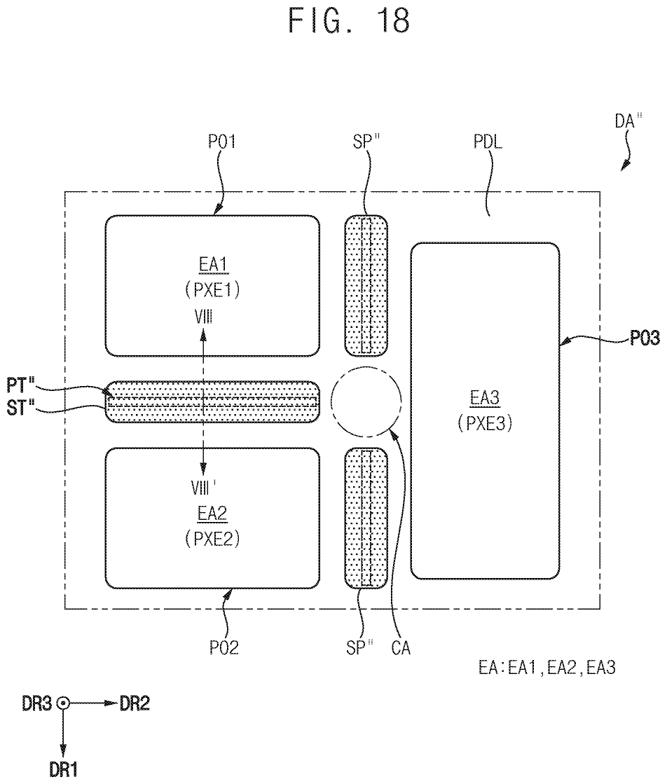

FIG. 18 is a schematic plan view illustrating a display area of a display device according to another embodiment.

Referring to FIG. 18, a display device according to another embodiment may include a pixel defining layer PDL, a pattern part PT″, and a separator SP″ disposed in a display area DA″.

The pixel defining layer PDL may be substantially same as the pixel defining layer PDL described with reference to FIG. 1.

The separator SP″ may be disposed on the pixel defining layer PDL between two adjacent emission areas. In this case, the separator SP″ may be disposed overlapping a line connecting the shortest distance on a plane between the two adjacent emission areas.

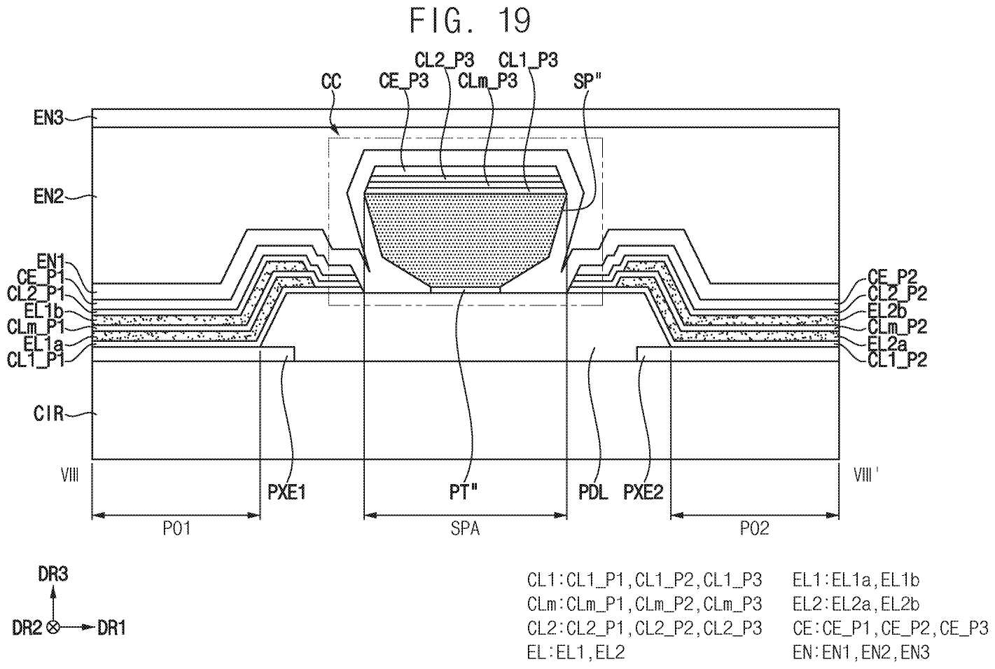

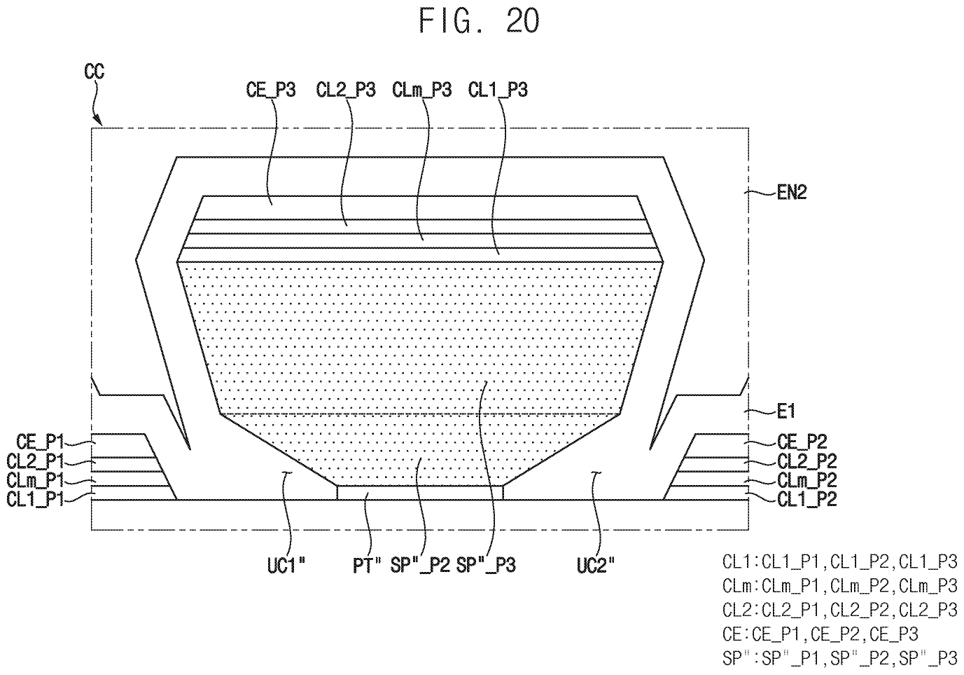

The pattern part PT″ may be disposed between the separator SP″ and the pixel defining layer PDL. The pattern part PT″ will be described below in detail with reference to FIGS. 19 and 20.

The connection area CA may be a partial area on the pixel defining layer PDL spaced apart from the separator SP″. The connection area CA may be substantially same as (or similar to) the connection area CA described with reference to FIGS. 1 and 4.

FIG. 19 is a schematic cross-sectional view taken along line VIII-VIII′ of FIG. 18. FIG. 20 is a schematic enlarged cross-sectional view of area CC of FIG. 19.

Referring to FIGS. 18 to 20, a display device according to another embodiment may include a circuit layer CIR, a first pixel electrode PXE1, a second pixel electrode PXE2, a pixel defining layer PDL, an organic light emitting material EL, a first functional layer CL1, an intermediate functional layer CLm, a second functional layer CL2, a common electrode layer CE, a pattern part PT″, a separator SP″, and an encapsulation layer EN.

In this case, the circuit layer CIR, the first pixel electrode PXE1, the second pixel electrode PXE2, the pixel defining layer PDL, the organic light emitting material EL, the first functional layer CL1, the intermediate functional layer CLm, the second functional layer CL2, the common electrode layer CE, and the encapsulation layer EN according to another embodiment may be substantially same as (or similar to) the circuit layer CIR, the first pixel electrode PXE1, the second pixel electrode PXE2, the pixel defining layer PDL, the organic light emitting material EL, the first functional layer CL1, the intermediate functional layer CLm, the second functional layer CL2, the common electrode layer CE, and the encapsulation layer EN described with reference to FIGS. 1 and 4. Therefore, descriptions of repetitive contents are omitted.

The pattern part PT″ may be disposed on the pixel defining layer PDL between the first pixel opening PO1 and the second pixel opening PO2. Also, the separator SP″ may be disposed on the pattern part PT″. In this case, an area where the separator SP″ is disposed may be referred to as a separation area SPA.

The separator SP″ may include parts sequentially arranged in the third direction DR3. More specifically, the separator SP″ may include a first inclined part SP″_P2 disposed on the pattern part PT″ and a second inclined part SP″_P3 disposed on the first inclined part SP″_P1.

The first inclined part SP″_P1 may directly contact the pattern part PT″. In this case, the entirety of a lower surface of the first inclined part SP″_P1 may cover the entirety of an upper surface of the pattern part PT″.

A width of the first inclined part SP″_P1 may gradually increase in the third direction DR3. In other words, the first inclined part SP″_P1 may have a reverse taper shape with respect to the upper surface of the pixel defining layer PDL.

The first inclined part SP″_P1 may define an undercut space by being spaced apart from the pixel defining layer PDL. In this case, the undercut space may include a first undercut space UC1″ adjacent to the first pixel opening PO1 and a second undercut space UC2″ adjacent to the second pixel opening PO2.

A width of the second inclined part SP″_P2 may gradually increase in the third direction DR3. In other words, the second inclined part SP″_P2 may have a reverse taper shape with respect to the upper surface of the pixel defining layer PDL.

The first inclined part SP″_P1 may have a first average taper angle, and the second inclined part SP″_P2 may have a second average taper angle. The first average taper angle may refer to an average inclination degree of a side surface of the first inclined part SP″_P1 with respect to the third direction DR3, and the second average taper angle may refer to an average inclination degree of a side surface of the second inclined part SP″_P2 with respect to the third direction DR3. In this case, the second average taper angle may be smaller than the first average taper angle.

The separator SP″ may have substantially same (or similar) function as the separator SP described with reference to FIGS. 1 to 4.

More specifically, the separator SP″ may include a second inclined part SP_P2″ having a reverse taper shape. Accordingly, in case that each of the first functional layer CL1, the intermediate functional layer CLm, the second functional layer CL2, and the common electrode layer CE is entirely formed by a front deposition process or the like, the first functional layer CL1, the intermediate functional layer CLm, the second functional layer CL2, and the common electrode layer CE may not be substantially formed on a side surface of the second inclined part SP_P2″. Therefore, the first functional layer CL1, the intermediate functional layer CLm, the second functional layer CL2, and the common electrode layer CE may be disconnected by the second inclined part SP_P2″.

In this case, the first functional layer CL1, the intermediate functional layer CLm, the second functional layer CL2, and the common electrode layer CE may be formed on a side surface of the second inclined part SP_P2″ due to a process error, etc., and thus there may be a problem of the first functional layer CL1, the intermediate functional layer CLm, the second functional layer CL2, and the common electrode layer CE not being disconnected. To prevent this, in the disclosure, the separator SP″ may include the first inclined part SP_P1″ having the first average taper angle greater than the second average taper angle of the second inclined part SP_P2″. Accordingly, even if the first functional layer CL1, the intermediate functional layer CLm, the second functional layer CL2, and the common electrode layer CE are formed on the side surface of the second inclined part SP_P2″ due to a process error, etc., the first functional layer CL1, the intermediate functional layer CLm, the second functional layer CL2, and the common electrode layer CE may not be formed on the side surface of the first inclined part SP_P1″ (or within the first undercut space UC1″ and the second undercut space UC2″).

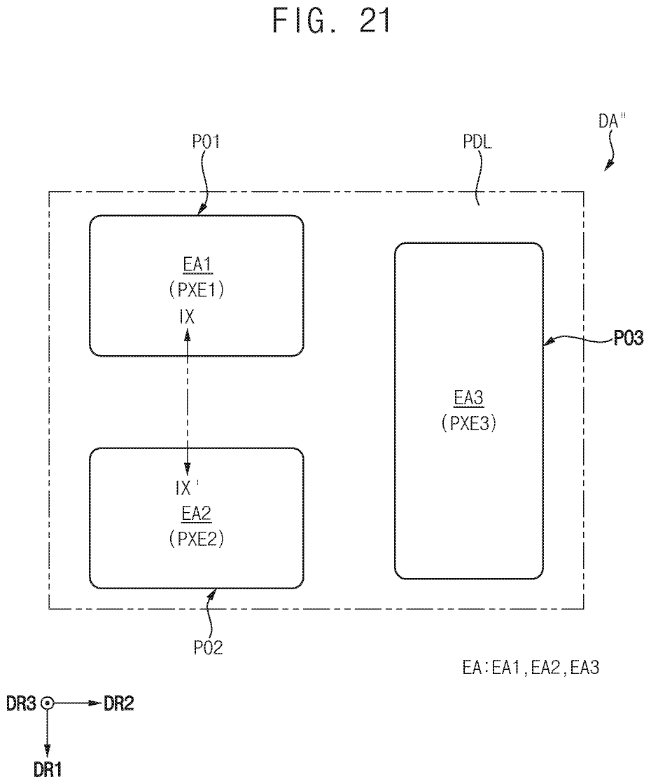

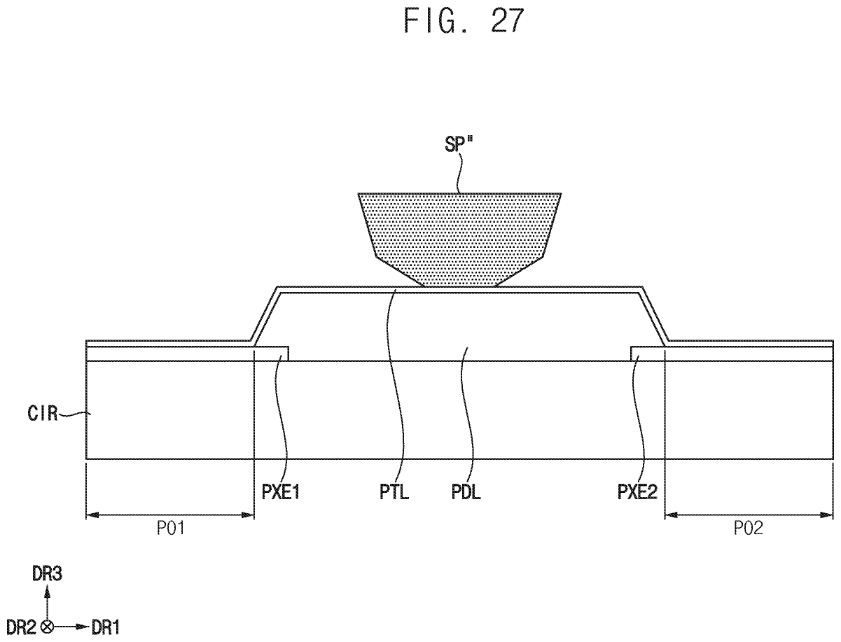

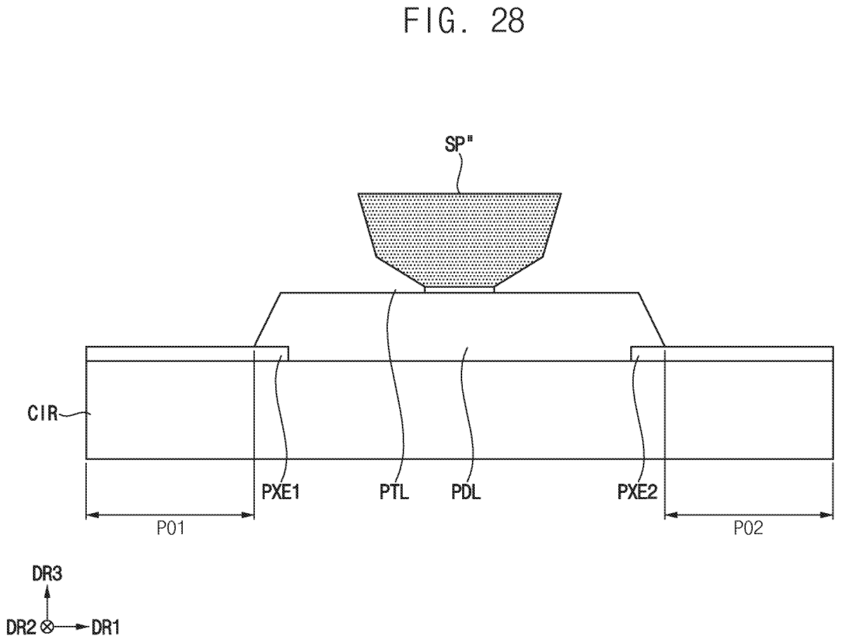

FIGS. 21 to 28 are schematic views illustrating a method of manufacturing a display device according to embodiment.

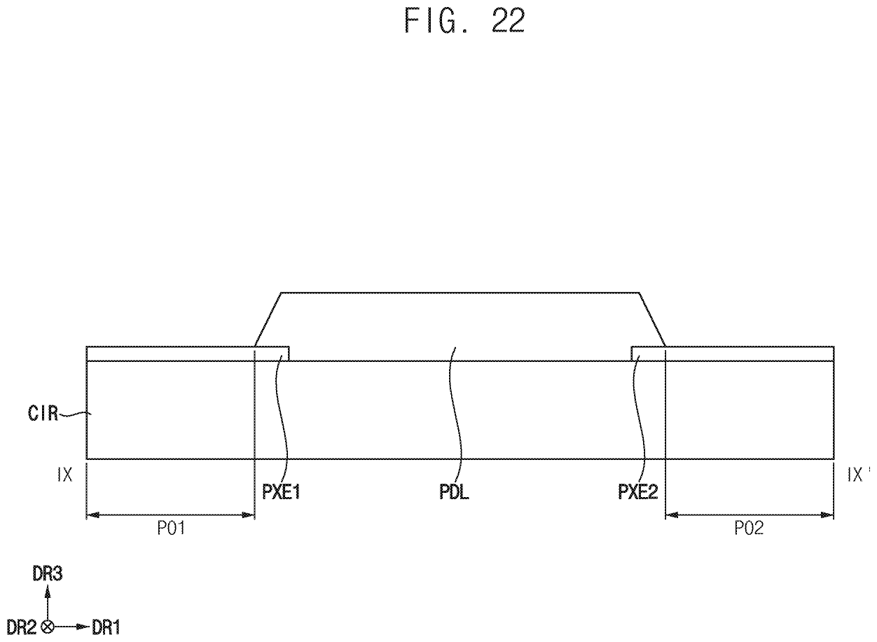

Referring to FIGS. 21 and 22, pixel electrodes spaced apart from each other may be formed on the circuit layer CIR. For example, the first pixel electrode PXE1 and the second pixel electrode PXE2 may be formed on the circuit layer CIR.

The pixel defining layer PDL may be formed on the circuit layer CIR to expose the pixel electrodes and define pixel openings spaced apart from each other. For example, the pixel defining layer PDL may define the first pixel opening PO1 exposing the first pixel electrode PXE1, the second pixel opening PO2 exposing the second pixel electrode PXE2, and the third pixel opening PO3 exposing the third pixel electrode PXE3.

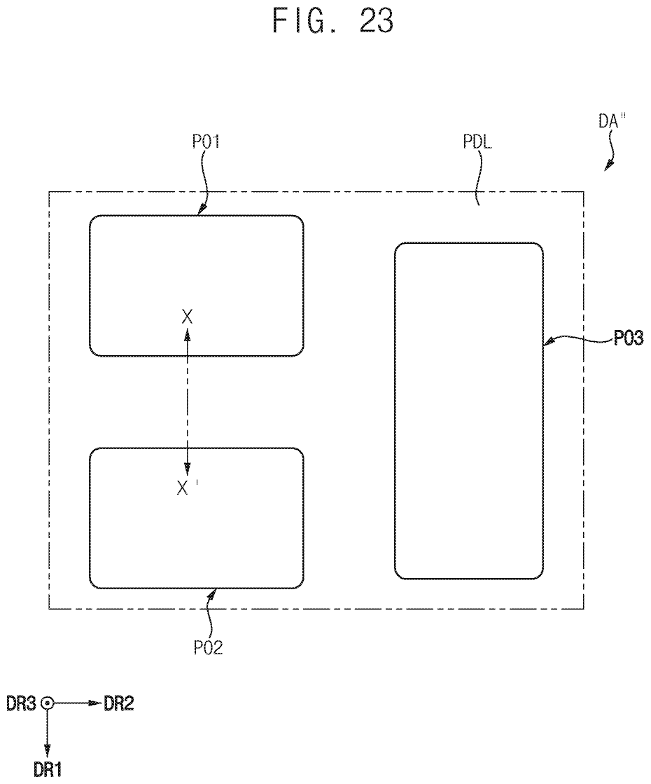

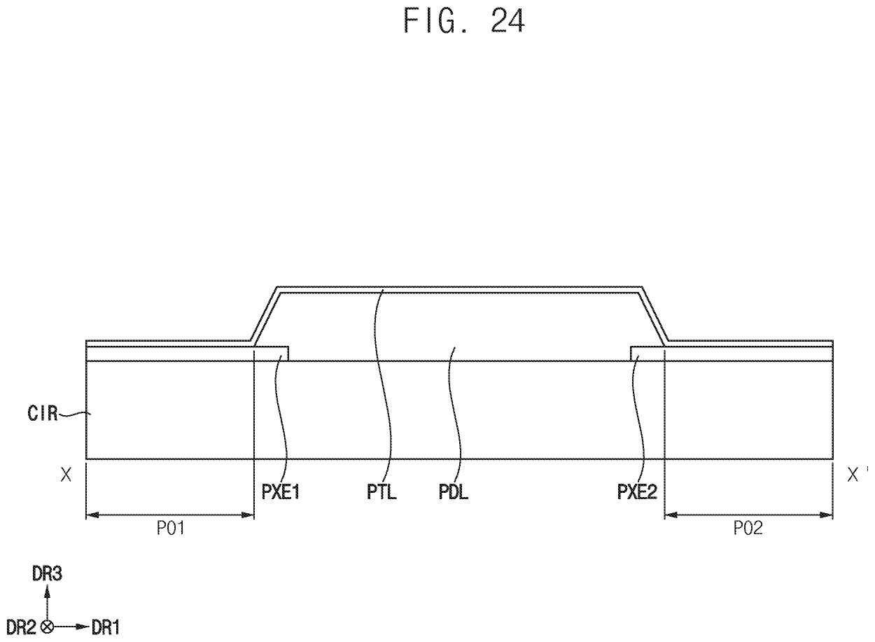

Referring to FIGS. 23 and 24, a pattern forming layer PTL may be entirely formed in the display area DA″. In this case, as shown in FIG. 24, the pattern forming layer PTL may entirely cover the pixel defining layer PDL, the first pixel electrode PXE1 exposed by the first pixel opening PO1, and the second pixel electrode PXE2 exposed by the second pixel opening PO2.

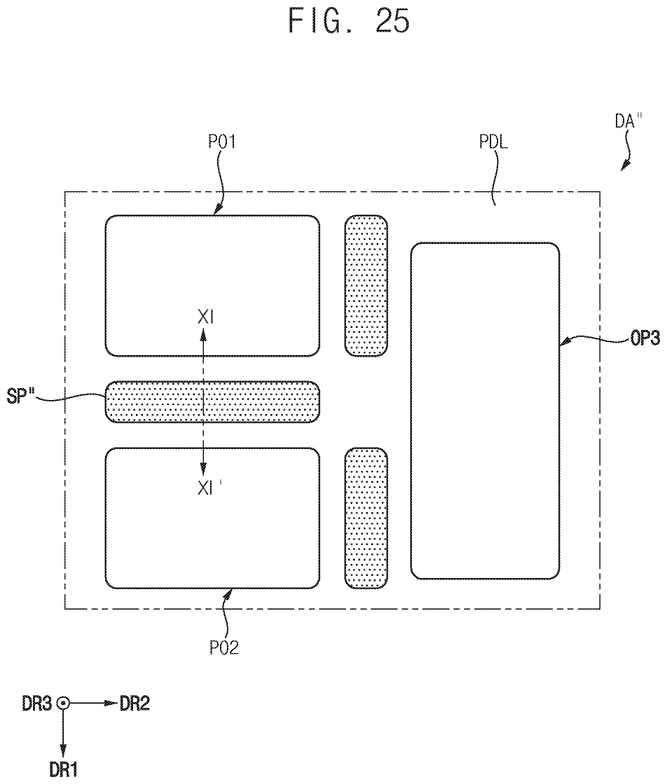

Referring to FIGS. 25 to 28, after forming the separator SP″, the pattern forming layer PTL may be patterned to form the pattern part PT″.

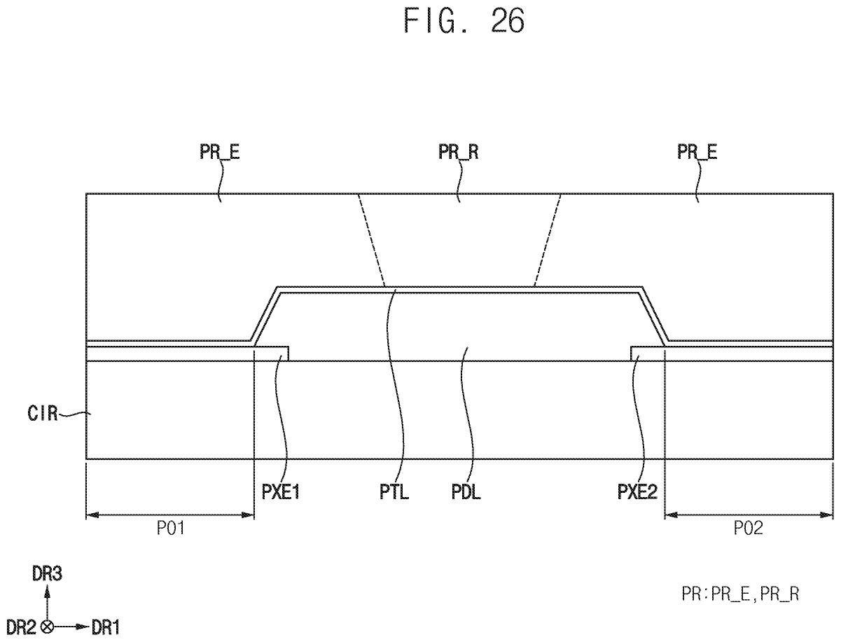

More specifically, as shown in FIG. 26, the photoresist layer PR may be entirely coated on the display area DA. In this case, the photoresist layer PR may entirely cover the pattern forming layer PTL.

After the photoresist layer PR is coated, a portion of the photoresist layer PR may be exposed to form a removed portion PR_E and a remaining portion PR_R. In case that the photoresist layer PR is a positive type, the removed portion PR_E may be exposed, and thus, the removed portion PR_E may be removed in a developing process to be described below. As another example, in case that the photoresist layer PR is a negative type, the remaining portion PR_R may be exposed, and thus, the removed portion PR_E excluding the remaining portion PR_R may be removed in a developing process described below.

After exposing the photoresist layer PR, the removed portion PR_E may be removed by developing the photoresist layer PR with a developing solution. In this case, the developing solution may penetrate into an interface between the remaining portion PR_R and the pattern forming layer PTL, and thus, the separator SP″ described above with FIG. 20 may be formed.

As described above, the separator SP″ may be formed by interfacial penetration of the developing solution. To this end, pattern forming layer PTL (or the pattern part PT″) may include a material having relatively weak adhesive strength to a material included in the separator SP″ (e.g., a material included in the photoresist layer PR). For example, the separator SP″ may include a photosensitive organic material, and the photosensitive organic material may have hydrophobic properties. In this case, the pattern forming layer PTL may include a hydrophilic material (e.g., metal, metal oxide, inorganic insulating material, etc.), and thus interfacial penetration of the developing solution may be facilitated.

After forming the separator SP″, the pattern part PT″ may be formed by patterning the pattern forming layer PTL using the separator SP″ as a mask.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments.

The protection scope of the disclosure should be interpreted by the following claims, and it should be interpreted that all technical spirits within the equivalent scope are included in the scope of the disclosure.

What is claimed is:

1. A display device comprising:
a pixel defining layer defining:
a first pixel opening exposing a first pixel electrode; and
a second pixel opening exposing a second pixel electrode and spaced apart from the first pixel opening;
a pattern part disposed on the pixel defining layer between the first pixel opening and the second pixel opening and including a first pattern and a second pattern spaced apart from each other; and
a separator including:
a contact part directly contacting the pixel defining layer between the first pattern and the second pattern;
a first inclined part disposed on the contact part, spaced apart from the pattern part to define an undercut space, and having a first average taper angle; and
a second inclined part disposed on the first inclined part and having a second average taper angle smaller than the first average taper angle of the first inclined part.

2. The display device of claim 1, wherein
in a cross section, a width of the first inclined part gradually increases in a direction away from an upper surface of the pixel defining layer, and
in the cross section, a width of the second inclined part gradually increases in a direction away from an upper surface of the pixel defining layer.

3. The display device of claim 1, wherein the undercut space defined by the first inclined part includes:
a first undercut space defined by the first pattern and the first inclined part spaced apart from each other; and
a second undercut space defined by the second pattern and the first inclined part spaced apart from each other.

4. The display device of claim 1, wherein
the first pattern is closer to the first pixel opening than the second pattern, and
the second pattern is closer to the second pixel opening than the first pattern.

5. The display device of claim 4, wherein the contact part covers an entirety of an upper surface of the pixel defining layer between the first pattern and the second pattern spaced apart from each other.

6. The display device of claim 5, further comprising:
a first emission layer disposed in the first pixel opening;
a second emission layer disposed in the second pixel opening; and
a common layer electrically connected to each of the first emission layer and the second emission layer.

7. The display device of claim 6, wherein the common layer includes:
a first portion extending from within the first pixel opening onto the pixel defining layer adjacent to the first pixel opening;
a second portion extending from within the second pixel opening onto the pixel defining layer adjacent to the second pixel opening; and
a third portion disposed on the separator.

8. The display device of claim 7, wherein in an area between the first pixel opening and the second pixel opening, each of the first portion of the common layer and the second portion of the common layer is spaced apart from the third portion of the common layer.

9. The display device of claim 8, wherein in a connection area adjacent to the area between the first pixel opening and the second pixel opening and spaced apart from the separator, each of the first portion of the common layer and the second portion of the common layer electrically contacts the third portion of the common layer.

10. A display device comprising:
a pixel defining layer defining:
a first pixel opening exposing a first pixel electrode; and
a second pixel opening exposing a second pixel electrode and spaced apart from the first pixel opening; and
a separator including:
a contact part directly contacting the pixel defining layer;
a first inclined part disposed on the contact part, spaced apart from the pixel defining layer to define an undercut space, and having a first average taper angle; and
a second inclined part disposed on the first inclined part and having a second average taper angle smaller than the first average taper angle of the first inclined part.

11. The display device of claim 10, wherein
in a cross section, a width of the first inclined part gradually increases in a direction away from an upper surface of the pixel defining layer, and
in the cross section, a width of the second inclined part gradually increases in a direction away from an upper surface of the pixel defining layer.

12. The display device of claim 10, wherein the undercut space defined by the first inclined part includes:
a first undercut space adjacent to the first pixel opening; and
a second undercut space adjacent to the second pixel opening.

13. The display device of claim 10, further comprising:
a first emission layer disposed in the first pixel opening;
a second emission layer disposed in the second pixel opening; and
a common layer electrically connected to each of the first emission layer and the second emission layer.

14. The display device of claim 13, wherein the common layer includes:
a first portion extending from within the first pixel opening onto the pixel defining layer adjacent to the first pixel opening;
a second portion extending from within the second pixel opening onto the pixel defining layer adjacent to the second pixel opening; and
a third portion disposed on the separator.

15. The display device of claim 14, wherein in an area between the first pixel opening and the second pixel opening, each of the first portion of the common layer and the second portion of the common layer is spaced apart from the third portion of the common layer.

16. The display device of claim 15, wherein in a connection area adjacent to the area between the first pixel opening and the second pixel opening and spaced apart from the separator, each of the first portion of the common layer and the second portion of the common layer electrically contacts the third portion of the common layer.

17. A display device comprising:
a pixel defining layer defining:
a first pixel opening exposing a first pixel electrode; and
a second pixel opening exposing a second pixel electrode and spaced apart from the first pixel opening;
a pattern part disposed on the pixel defining layer between the first pixel opening and the second pixel opening; and
a separator including:
a first inclined part disposed on the pattern part, spaced apart from the pixel defining layer to define an undercut space, and having a first average taper angle; and
a second inclined part disposed on the first inclined part and having a second average taper angle smaller than the first average taper angle of the first inclined part.

18. The display device of claim 17, wherein
in a cross section, a width of the first inclined part gradually increases in a direction away from an upper surface of the pixel defining layer, and
in the cross section, a width of the second inclined part gradually increases in a direction away from an upper surface of the pixel defining layer.

19. The display device of claim 17, wherein the first inclined part directly contacts the pattern part.

20. The display device of claim 17, wherein the undercut space defined by the first inclined part includes:
a first undercut space adjacent to the first pixel opening; and
a second undercut space adjacent to the second pixel opening.

21. The display device of claim 17, further comprising:
a first emission layer disposed in the first pixel opening;
a second emission layer disposed in the second pixel opening; and
a common layer electrically connected to each of the first emission layer and the second emission layer.

22. The display device of claim 21, wherein the common layer includes:
a first portion extending from within the first pixel opening onto the pixel defining layer adjacent to the first pixel opening;
a second portion extending from within the second pixel opening onto the pixel defining layer adjacent to the second pixel opening; and
a third portion disposed on the separator.

23. The display device of claim 22, wherein in an area between the first pixel opening and the second pixel opening, each of the first portion of the common layer and the second portion of the common layer is spaced apart from the third portion of the common layer.

24. The display device of claim 23, wherein in a connection area adjacent to the area between the first pixel opening and the second pixel opening and spaced apart from the separator, each of the first portion of the common layer and the second portion of the common layer electrically contacts the third portion of the common layer.
